(19) United States
(12) Patent Application Publication
(10) Pub. No.: US 2009/0039487 A1
(43) Pub. Date: Feb. 12, 2009

(54) SEMICONDUCTOR DEVICE

(75) Inventors: Keiichi Kawashima, Tokyo (JP); Naohito Yoshida, Tokyo (JP); Takeshi Hosomi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/166,414

(22) Filed: Jul. 2, 2008

(30) Foreign Application Priority Data
Aug. 10, 2007 (JP) 2007-209043
Dec. 20, 2007 (JP) 2007-328904
Apr. 15, 2008 (JP) 2008-105528

(51) Int. Cl. H01L 23/495

(52) U.S. Cl. 257/676; 257/E23.031

(57) ABSTRACT

A semiconductor device comprises a source frame having a die pad; a linear gate frame having a bonding pad; a semiconductor chip mounted on the die pad; wires which electrically connect a source terminal of the semiconductor chip to the die pad and electrically connect a gate terminal of the semiconductor chip to the bonding pad; and resin which seals the die pad, the bonding pad, the semiconductor chip, and the wires. The die pad is spaced from the bonding pad and diagonal to an extending direction of the gate frame, in the vicinity of the bonding pad.

### BACKGROUND OF THE INVENTION

1. Field of the Invention

The present invention relates to a semiconductor device capable of reducing a noise factor without changing an external shape.

2. Background Art

A semiconductor device is used in which a semiconductor chip with a high-frequency element such as a GaAs FET formed thereon is mounted on a source frame and sealed with resin (e.g., see Japanese Patent Laid-Open No. 61-16554).

FIG. 20 is a plan view showing a conventional semiconductor device. FIG. 21 is a perspective view showing a conventional semiconductor device. A source frame 1 has a die pad 2 in the center. A semiconductor chip 3 is mounted on this die pad 2. Furthermore, a linear gate frame 4 and a drain frame 5 are provided at a certain distance from the source frame 1. The gate frame 4 and drain frame 5 have bonding pads 6 and 7 respectively.

Furthermore, a source terminal 9 of the semiconductor chip 3 and the die pad 2 are electrically connected by a plurality of wires 8, a drain terminal 10 of the semiconductor chip 3 and the bonding pad 7 are electrically connected, and a gate terminal 11 of the semiconductor chip 3 and the bonding pad 6 are electrically connected. The die pad 2, the bonding pads 6 and 7, the semiconductor chip 3 and the plurality of wires 8 are sealed with mold resin 12.

### SUMMARY OF THE INVENTION

In the conventional semiconductor device, the die pad 2 is cut into a rectangular shape and the bonding pad 6 is cut along the shape of the die pad 2. In this way, the space between the source frame 1 and the gate frame 4 is narrow and the area that both frames face each other is large. As a result, a capacitance between the source frame 1 and gate frame 4 is increased. Moreover, as is seen from following Formulas (1) and (2), there is a problem that as a capacitance Cgs between the source frame 1 and gate frame 4 increases, a noise factor NF increases.

$$\begin{matrix}NF = 1 + \frac{ω}{{f}_{T}} \sqrt{A} & ( 1 ) \\ {f}_{T} ∝ \frac{1}{{C}_{gs}} & ( 2 )\end{matrix}$$

Here, NF is a noise factor, ω is an angular frequency, f_{T} is a current gain cutoff frequency, A is a constant and Cgs is a source-gate capacitance.

A noise factor of a semiconductor device may be reduced by changing the external shape of the semiconductor device, increasing the space between the source frame 1 and the gate frame 4 and reducing the area that both frames face each other. However, it is difficult to change the external shape since the size of the semiconductor device is standardized and from the standpoint of manufacturing cost.

Furthermore, as is understandable from Formula (3) below, a capacitance Cdg between the gate frame 4 and the drain frame 5 may be decreased to increase the gain (maximum effective gain) of the semiconductor device.

$$MAG = \frac{B}{Cdg} ( k - \sqrt{{k}^{2} - 1} ) \qquad ( 3 )$$

Here, MAG is a maximum effective gain, k is a stability factor, B is a constant and Cdg is the capacitance between the drain and the gate.

Electrical coupling between the gate and the drain needs to be weakened to decrease Cdg. This requires the capacitance Cgs between the gate and the source and the capacitance Cds between the drain and the source to be increased. When Cgs is increased, the noise factor is increased according to Formula (I). Therefore, if Cds is increased, the gain can be increased without increasing the noise factor.

Cds may be increased by changing the external shape of the semiconductor device and increasing the area that the source frame 1 and the drain frame 5 face each other. However, it is difficult to change the external shape because the size of the semiconductor device is standardized and from the standpoint of manufacturing cost.

The present invention has been implemented to solve the above described problem and it is a first object of the present invention to obtain a semiconductor device capable of decreasing a noise factor without changing the external shape.

It is a second object of the present invention to obtain a semiconductor device capable of increasing a gain without changing the external shape.

According to one aspect of the present invention, a semiconductor device comprises a source frame having a die pad; a linear gate frame having a bonding pad; a semiconductor chip mounted on the die pad; a plurality of wires which electrically connect a source terminal of the semiconductor chip and the die pad and electrically connect a gate terminal of the semiconductor chip and the bonding pad; and resin which seals the die pad, the bonding pad, the semiconductor chip and the plurality of wires, wherein the die pad is provided at a certain distance from the bonding pad and cut in a direction diagonally to an extending direction of the gate frame in the vicinity of the bonding pad.

The invention can decrease the noise factor of the semiconductor device without changing the external shape.

Other and further objects, features and advantages of the invention will appear more fully from the following description.

### BRIEF DESCRIPTION OF THE DRAWINGS

FIG. 1 is a plan view showing a semiconductor device according to Embodiment 1 of the present invention.

FIG. 2 is a plan view showing a semiconductor device according to Embodiment 2 of the present invention.

FIG. 3 is a plan view showing a semiconductor device according to Embodiment 3 of the present invention.

FIG. 4 is a plan view showing a semiconductor device according to Embodiment 4 of the present invention.

FIG. 5 is a plan view showing a semiconductor device according to Embodiment 5 of the present invention.

FIG. 6 is a plan view showing a semiconductor device according to Embodiment 6 of the present invention.

FIG. 7 is a perspective view showing a semiconductor device according to Embodiment 7 of the present invention.

FIG. 8 is a perspective view showing a semiconductor device according to Embodiment 8 of the present invention.

FIG. 9 is a perspective view showing a semiconductor device according to Embodiment 9 of the present invention.

FIG. 10 is a perspective view showing a semiconductor device according to Embodiment 10 of the present invention.

FIG. 11 is a plan view showing a semiconductor device according to Embodiment 11 of the present invention.

FIG. 12 is a plan view showing a semiconductor device according to Embodiment 12 of the present invention.

FIG. 13 is a plan view showing a semiconductor device according to Embodiment 13 of the present invention.

FIG. 14 is a plan view showing a semiconductor device according to Embodiment 14 of the present invention.

FIG. 15 is a plan view showing a semiconductor device according to Embodiment 15 of the present invention.

FIG. 16 is a perspective view showing a semiconductor device according to Embodiment 16 of the present invention.

FIG. 17 is a perspective view showing a semiconductor device according to Embodiment 17 of the present invention.

FIG. 18 is a perspective view showing a semiconductor device according to Embodiment 18 of the present invention.

FIG. 19 is a perspective view showing a semiconductor device according to Embodiment 19 of the present invention.

FIG. 20 is a plan view showing a conventional semiconductor device.

FIG. 21 is a perspective view showing a conventional semiconductor device.

### DETAILED DESCRIPTION OF THE PREFERRED EMBODIMENTS

### Embodiment 1

FIG. 1 is a plan view showing a semiconductor device according to Embodiment 1 of the present invention. A source frame 1 has a die pad 2 in the center. A semiconductor chip 3 is mounted on this die pad 2. A high-frequency element such as a GaAs FET is formed on the semiconductor chip 3. Furthermore, a linear gate frame 4 and a drain frame 5 are provided at a certain distance from the source frame 1. These gate frame 4 and drain frame 5 have bonding pads 6 and 7 respectively.

Furthermore, a source terminal 9 of the semiconductor chip 3 and the die pad 2 are electrically connected by a plurality of wires 8, a drain terminal 10 of the semiconductor chip 3 and the bonding pad 7 are electrically connected, a gate terminal 11 of the semiconductor chip 3 and the bonding pad 6 are electrically connected. The die pad 2, the bonding pads 6 and 7, the semiconductor chip 3 and the plurality of wires 8 are sealed with mold resin 12 (resin).

According to this embodiment, the die pad 2 is cut in a direction diagonal to the extending direction of the gate frame 4 in the vicinity of the bonding pad 6. That is, the die pad 2 is cut in a direction in which it goes away from the gate frame 4 in the vicinity of the bonding pad 6. On the other hand, the bonding pad 6 is cut in parallel with a diagonally cut portion of the die pad 2 in the vicinity of the die pad 2.

The above described configuration makes it possible to increase the distance between the source frame 1 and the gate frame 4 and reduce the area that both frames face each other. Therefore, it is possible to reduce a capacitance between the source frame 1 and the gate frame 4 and thereby reduce the noise factor of the semiconductor device without changing the external shape.

### Embodiment 2

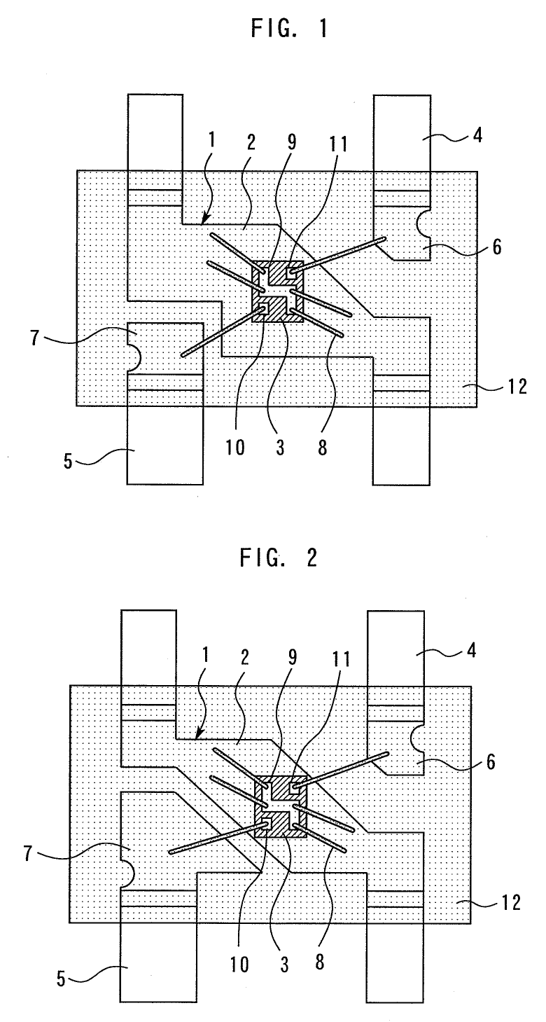

FIG. 2 is a plan view showing a semiconductor device according to Embodiment 2 of the present invention. A drain frame 5 is wider at a bonding pad 7. The portions of a die pad 2 and the bonding pad 7 that face each other are cut in a direction diagonal to the extending direction of the drain frame 5 respectively. The rest of the configuration is the same as that of Embodiment 1.

The above described configuration can increase the area that a source frame 1 and the drain frame 5 face each other. Therefore, since the capacitance between the source frame 1 and the drain frame 5 can be increased, a gain can be increased without changing the external shape. Other effects are the same as those of Embodiment 1.

### Embodiment 3

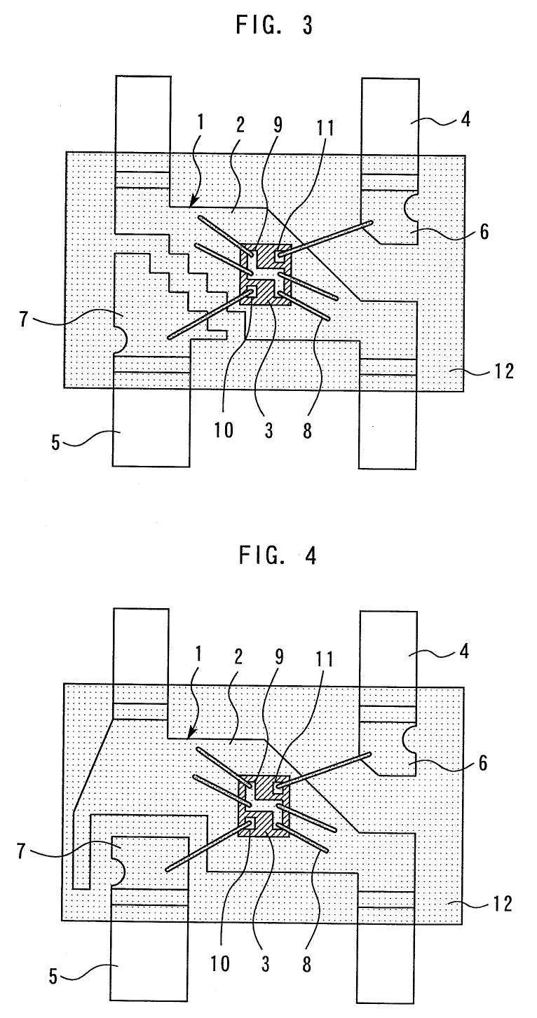

FIG. 3 is a plan view showing a semiconductor device according to Embodiment 3 of the present invention. A drain frame 5 is wider at a bonding pad 7. The portions of a die pad 2 and the bonding pad 7 that face each other are cut into a stepped shape. The rest of the configuration is the same as that of Embodiment 1.

The above described configuration can increase the area that a source frame 1 and the drain frame 5 face each other more than Embodiment 2. This can further increase a gain. Other effects are the same as those of Embodiment 1.

### Embodiment 4

FIG. 4 is a plan view showing a semiconductor device according to Embodiment 4 of the present invention. A die pad 2 surrounds the outer perimeter of a bonding pad 7 in a U shape. The rest of the configuration is the same as that of Embodiment 1.

The above described configuration can increase the area that a source frame 1 and a drain frame 5 face each other. Therefore, since a capacitance between the source frame 1 and the drain frame 5 can be increased, a gain can be increased without changing the external shape. Other effects are the same as those of Embodiment 1.

### Embodiment 5

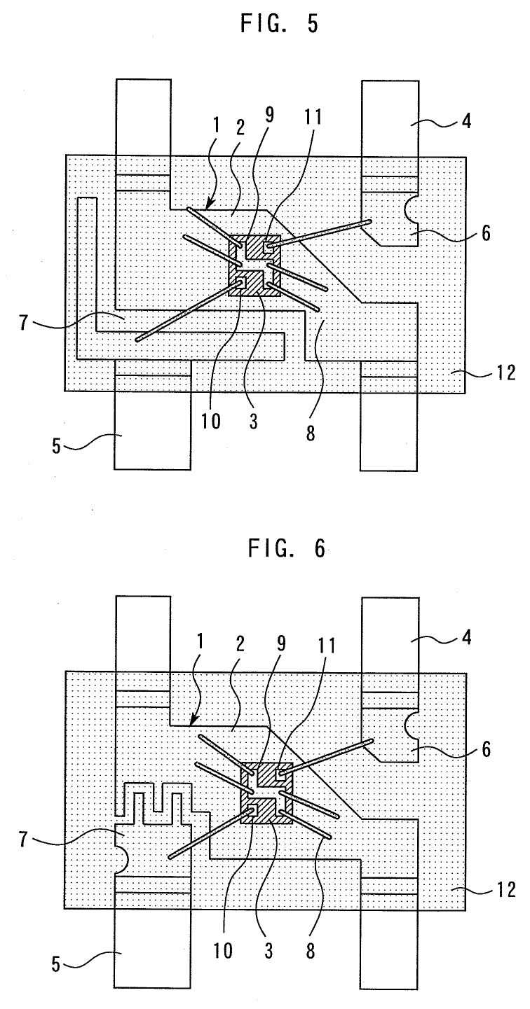

FIG. 5 is a plan view showing a semiconductor device according to Embodiment 5 of the present invention. A bonding pad 7 surrounds the outer perimeter of a die pad 2 in an L shape. The rest of the configuration is the same as that of Embodiment 1.

The above described configuration can increase the area that a source frame 1 and a drain frame 5 face each other. Therefore, since a capacitance between the source frame 1 and the drain frame 5 can be increased a gain can be increased without changing the external shape. Other effects are the same as those of Embodiment 1.

### Embodiment 6

FIG. 6 is a plan view showing a semiconductor device according to Embodiment 6 of the present invention. The portions of a die pad 2 and a bonding pad 7 that face each other have an inter-digital structure. The rest of the configuration is the same as that of Embodiment 1.

The above described configuration can increase the area that a source frame 1 and a drain frame 5 face each other. Therefore, since a capacitance between the source frame 1 and the drain frame 5 can be increased, a gain can be increased without changing the external shape. Other effects are the same as those of Embodiment 1.

### Embodiment 7

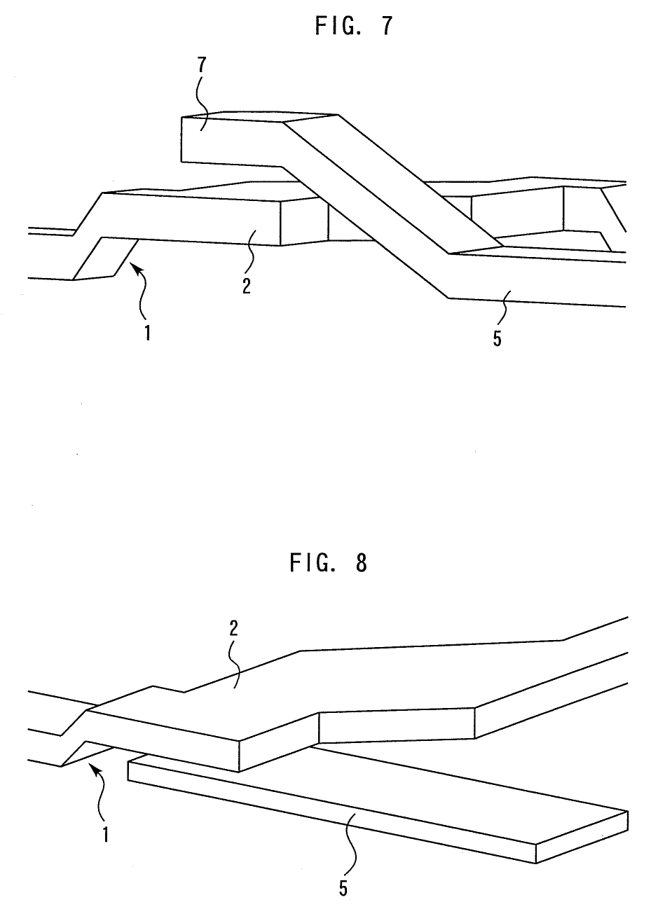

FIG. 7 is a perspective view showing a semiconductor device according to Embodiment 7 of the present invention. A bonding pad 7 is disposed above a die pad 2. The rest of the configuration is the same as that of Embodiment 1.

The above described configuration can increase the area that a source frame 1 and a drain frame 5 face each other. Therefore, since a capacitance between the source frame 1 and the drain frame 5 can be increased, a gain can be increased without changing the external shape. Other effects are the same as those of Embodiment 1.

### Embodiment 8

FIG. 8 is a perspective view showing a semiconductor device according to Embodiment 8 of the present invention. A drain frame 5 is disposed below a die pad 2. No bonding pad 7 is provided for the drain frame 5, and the drain frame 5 and a drain terminal 10 of a semiconductor chip 3 are wire-bonded. The rest of the configuration is the same as that of Embodiment 1.

The above described configuration can increase the area that a source frame 1 and the drain frame 5 face each other. Therefore, since a capacitance between the source frame 1 and the drain frame 5 can be increased, a gain can be increased without changing the external shape. Other effects are the same as those of Embodiment 1.

### Embodiment 9

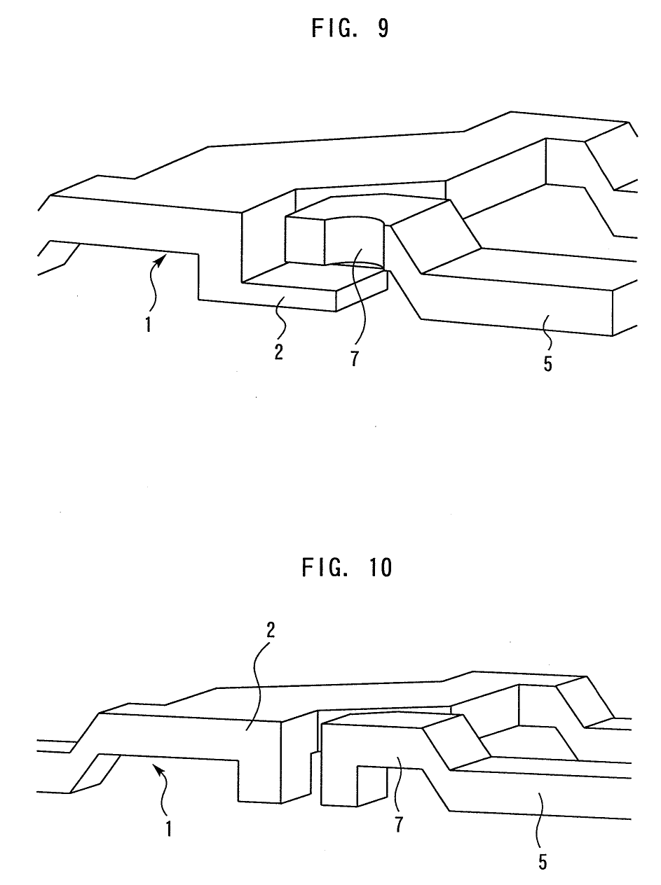

FIG. 9 is a perspective view showing a semiconductor device according to Embodiment 9 of the present invention. A die pad 2 extends below a bonding pad 7. The rest of the configuration is the same as that of Embodiment 1.

The above described configuration can increase the area that a source frame 1 and a drain frame 5 face each other. Therefore, since a capacitance between the source frame 1 and the drain frame 5 can be increased, a gain can be increased without changing the external shape. Other effects are the same as those of Embodiment 1.

### Embodiment 10

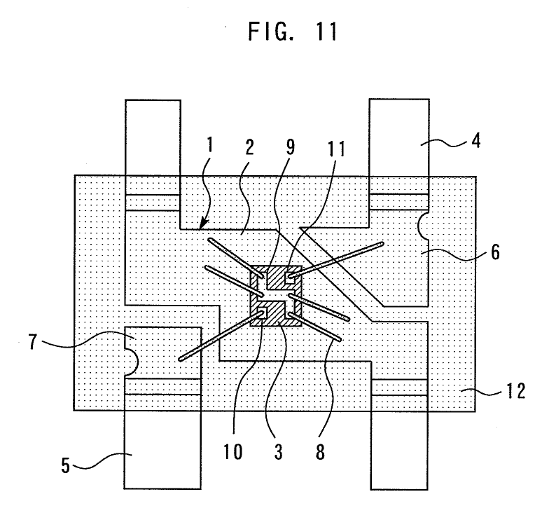

FIG. 10 is a perspective view showing a semiconductor device according to Embodiment 10 of the present invention. The portions of a die pad 2 and a bonding pad 7 that face each other extend downward. The rest of the configuration is the same as that of Embodiment 1.

The above described configuration can increase the area that a source frame 1 and a drain frame 5 face each other. Therefore, since a capacitance between the source frame 1 and the drain frame 5 can be increased, a gain can be increased without changing the external shape. Other effects are the same as those of Embodiment 1.

### Embodiment 11

FIG. 11 is a plan view showing a semiconductor device according to Embodiment 11 of the present invention. A gate frame 4 is wider at a bonding pad 6. The portions of a die pad 2 and the bonding pad 6 that face each other are cut in a direction diagonal to the extending direction of the gate frame 4 respectively. The rest of the configuration is the same as that of Embodiment 1.

The above described configuration can increase the area that a source frame 1 and the gate frame 4 face each other. Therefore, since the capacitance between the source frame 1 and the gate frame 4 can be increased, a gain can be increased without changing the external shape.

### Embodiment 12

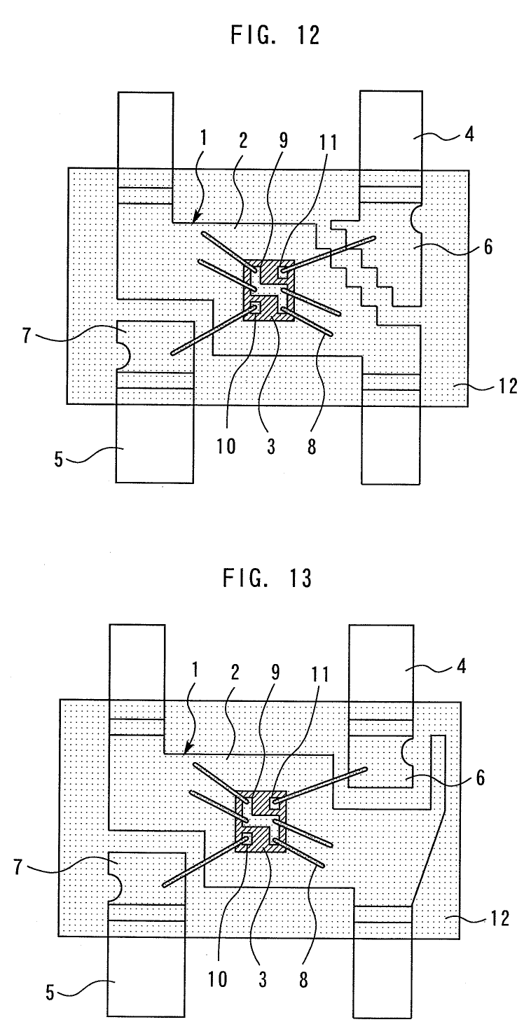

FIG. 12 is a plan view showing a semiconductor device according to Embodiment 12 of the present invention. A gate frame 4 is wider at a bonding pad 6. The portions of a die pad 2 and the bonding pad 6 that face each other are cut into a stepped shape. The rest of the configuration is the same as that of Embodiment 1.

The above described configuration can increase the area that a source frame 1 and the gate frame 4 face each other more than Embodiment 2. This can further increase a gain.

### Embodiment 13

FIG. 13 is a plan view showing a semiconductor device according to Embodiment 13 of the present invention. A die pad 2 surrounds the outer perimeter of a bonding pad 6 in a U shape. The rest of the configuration is the same as that of Embodiment 1.

The above described configuration can increase the area that a source frame 1 and a gate frame 4 face each other. Therefore, since a capacitance between the source frame 1 and the gate frame 4 can be increased, a gain can be increased without changing the external shape.

### Embodiment 14

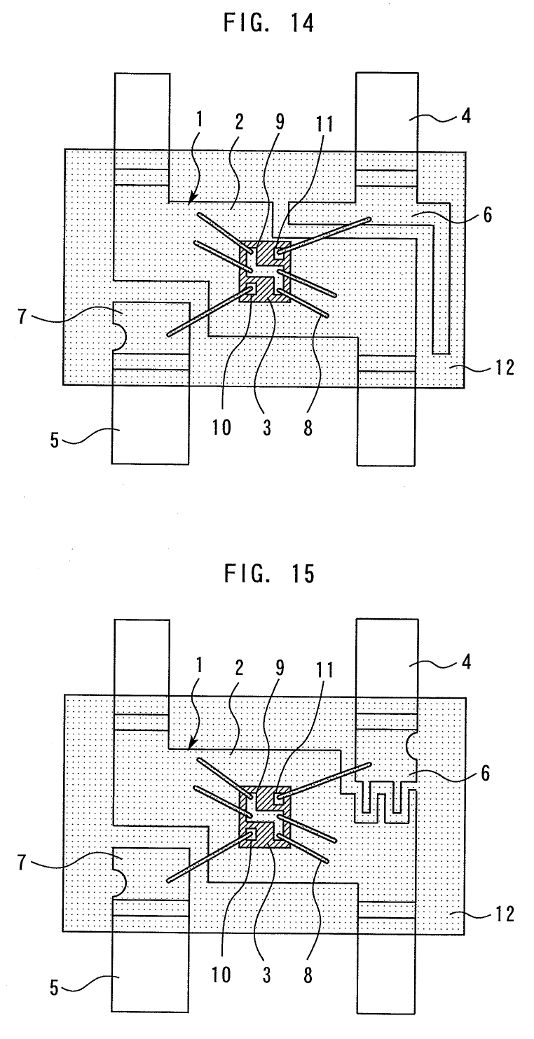

FIG. 14 is a plan view showing a semiconductor device according to Embodiment 14 of the present invention. A bonding pad 6 surrounds the outer perimeter of a die pad 2 in an L shape. The rest of the configuration is the same as that of Embodiment 1.

The above described configuration can increase the area that a source frame 1 and a gate frame 4 face each other. Therefore, since a capacitance between the source frame 1 and the gate frame 4 can be increased, a gain can be increased without changing the external shape.

### Embodiment 15

FIG. 15 is a plan view showing a semiconductor device according to Embodiment 15 of the present invention. The portions of a die pad 2 and a bonding pad 6 that face each other have an inter-digital structure. The rest of the configuration is the same as that of Embodiment 1.

The above described configuration can increase the area that a source frame 1 and a gate frame 4 face each other. Therefore, since a capacitance between the source frame 1 and the gate frame 4 can be increased, a gain can be increased without changing the external shape.

### Embodiment 16

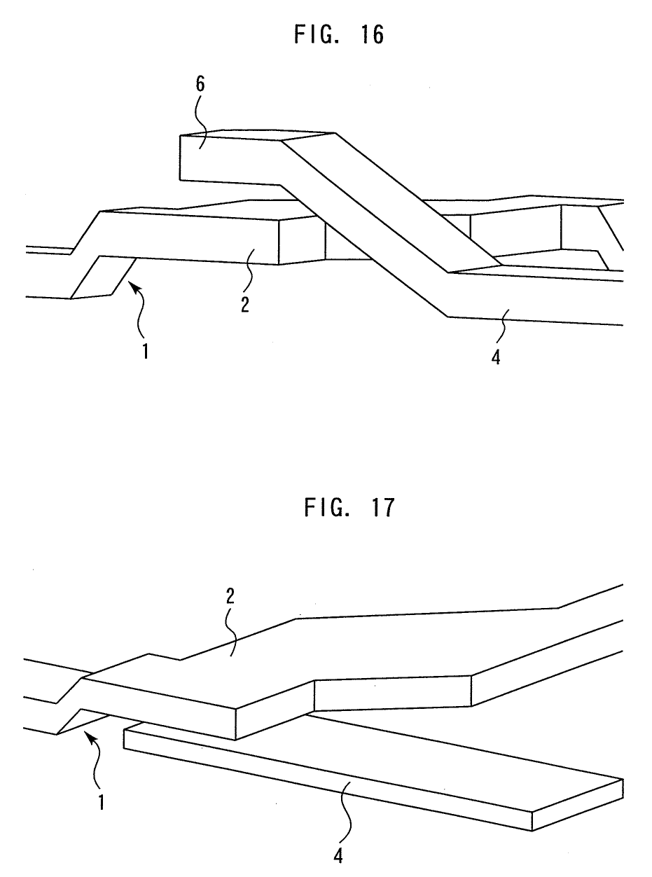

FIG. 16 is a perspective view showing a semiconductor device according to Embodiment 16 of the present invention. A bonding pad 6 is disposed above a die pad 2. The rest of the configuration is the same as that of Embodiment 1.

The above described configuration can increase the area that a source frame 1 and a gate frame 4 face each other. Therefore, since a capacitance between the source frame 1 and the gate frame 4 can be increased, a gain can be increased without changing the external shape.

### Embodiment 17

FIG. 17 is a perspective view showing a semiconductor device according to Embodiment 17 of the present invention. A gate frame 4 is disposed below a die pad 2. No bonding pad 6 is provided for the gate frame 4, and the gate frame 4 and a gate terminal 11 of a semiconductor chip 3 are wire-bonded. The rest of the configuration is the same as that of Embodiment 1.

The above described configuration can increase the area that a source frame 1 and the gate frame 4 face each other. Therefore, since a capacitance between the source frame 1 and the gate frame 4 can be increased, a gain can be increased without changing the external shape.

### Embodiment 18

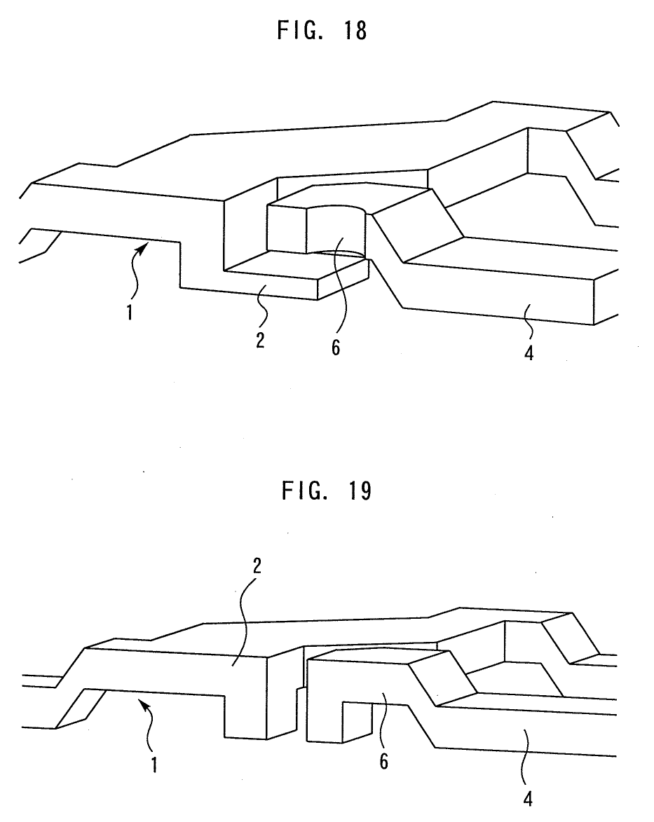

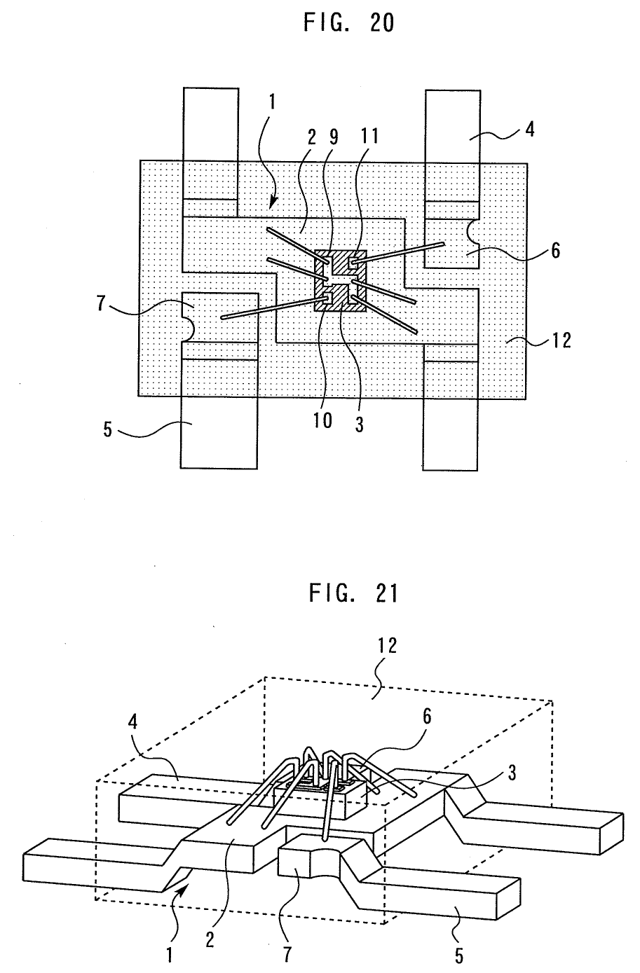

FIG. 18 is a perspective view showing a semiconductor device according to Embodiment 18 of the present invention. A die pad 2 extends below a bonding pad 6. The rest of the configuration is the same as that of Embodiment 1.

The above described configuration can increase the area that a source frame 1 and a gate frame 4 face each other. Therefore, since a capacitance between the source frame 1 and the gate frame 4 can be increased, a gain can be increased without changing the external shape.

### Embodiment 19

FIG. 19 is a perspective view showing a semiconductor device according to Embodiment 19 of the present invention. The portions of a die pad 2 and a bonding pad 6 that face each other extend downward. The rest of the configuration is the same as that of Embodiment 1.

The above described configuration can increase the area that a source frame 1 and a gate frame 4 face each other. Therefore, since a capacitance between the source frame 1 and the gate frame 4 can be increased, a gain can be increased without changing the external shape.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2007-209043 filed on Aug. 10, 2007, a Japanese Patent Application No. 2007-328904 filed on Dec. 20, 2007 and a Japanese Patent Application No. 2008-105528 filed on Apr. 15, 2008 including specification, claims, drawings and summary, on which the Convention priority of the present application is based, are incorporated herein by reference in its entirety.

1. A semiconductor device comprising:
a source frame having a die pad;
a linear gate frame having a bonding pad;
a semiconductor chip mounted on the die pad;
a plurality of wires which electrically connect a source terminal of the semiconductor chip to the die pad and electrically connect a gate terminal of the semiconductor chip to the bonding pad; and
resin which seals the die pad, the bonding pad, the semiconductor chip, and the plurality of wires, wherein the die pad is spaced from the bonding pad and cut in a direction diagonal to an extending direction of the gate frame, in the vicinity of the bonding pad.

2. The semiconductor device according to claim 1, wherein the bonding pad is parallel to a diagonally cut portion of the die pad, in the vicinity of the die pad.

3. A semiconductor device comprising:
a source frame having a die pad;
a linear drain frame having a bonding pad spaced from the die pad;
a semiconductor chip mounted on the die pad;
a plurality of wires which electrically connect a source terminal of the semiconductor chip to the die pad and electrically connect a drain terminal of the semiconductor chip to the bonding pad; and
resin which seals the die pad, the bonding pad, the semiconductor chip, and the plurality of wires, wherein the drain frame is wider at the bonding pad than elsewhere.

4. The semiconductor device according to claim 3, wherein portions of the die pad and the bonding pad that face each other are respectively diagonal to an extending direction of the drain frame.

5. The semiconductor device according to claim 3, wherein portions of the die pad and the bonding pad that face each other have a stepped shape.

6. A semiconductor device comprising:
a source frame having a die pad;
a drain frame having a bonding pad spaced from the die pad;
a semiconductor chip mounted on the die pad;
a plurality of wires which electrically connect a source terminal of the semiconductor chip to the die pad and electrically connect a drain terminal of the semiconductor chip to the bonding pad; and
resin which seals the die pad, the bonding pad, the semiconductor chip, and the plurality of wires, wherein the die pad surrounds an outer perimeter of the bonding pad in a U shape.

7. A semiconductor device comprising:
a source frame having a die pad;
a drain frame having a bonding pad spaced from the die pad;
a semiconductor chip mounted on the die pad;
a plurality of wires which electrically connect a source terminal of the semiconductor chip to the die pad and electrically connect a drain terminal of the semiconductor chip to the bonding pad; and
resin which seals the die pad, the bonding pad, the semiconductor chip, and the plurality of wires, wherein the bonding pad surrounds an outer perimeter of the die pad in an L shape.

8. A semiconductor device comprising:
a source frame having a die pad;
a drain frame having a bonding pad spaced from the die pad;
a semiconductor chip mounted on the die pad;
a plurality of wires which electrically connect a source terminal of the semiconductor chip to the die pad and electrically connect a drain terminal of the semiconductor chip to the bonding pad; and
resin which seals the die pad, the bonding pad, the semiconductor chip, and the plurality of wires, wherein portions of the die pad and the bonding pad that face each other have an inter-digitated structure.

9. A semiconductor device comprising:
a source frame having a die pad;
a drain frame having a bonding pad spaced from the die pad;
a semiconductor chip mounted on the die pad;
a plurality of wires which electrically connect a source terminal of the semiconductor chip to the die pad and electrically connect a drain terminal of the semiconductor chip to the bonding pad; and
resin which seals the die pad, the bonding pad, the semiconductor chip, and the plurality of wires, wherein the bonding pad is disposed above the die pad.

10. A semiconductor device comprising:
a source frame having a die pad;
a drain frame spaced from the die pad;
a semiconductor chip mounted on the die pad;
a plurality of wires which electrically connect a source terminal of the semiconductor chip to the die pad and electrically connect a drain terminal of the semiconductor chip to the drain frame; and
resin which seals the die pad, the bonding pad, the semiconductor chip, and the plurality of wires, wherein the drain frame is disposed below the die pad.

11. A semiconductor device comprising:
a source frame having a die pad;
a drain frame having a bonding pad spaced from the die pad;
a semiconductor chip mounted on the die pad;
a plurality of wires which electrically connect a source terminal of the semiconductor chip to the die pad and electrically connect a drain terminal of the semiconductor chip to the bonding pad; and
resin which seals the die pad, the bonding pad, the semiconductor chip, and the plurality of wires, wherein the die pad extends below the bonding pad.

12. A semiconductor device comprising:
a source frame having a die pad;
a drain frame having a bonding pad spaced from the die pad;
a semiconductor chip mounted on the die pad;
a plurality of wires which electrically connect a source terminal of the semiconductor chip to the die pad and electrically connect a drain terminal of the semiconductor chip to the bonding pad; and
resin which seals the die pad, the bonding pad, the semiconductor chip, and the plurality of wires, wherein portions of the die pad and the bonding pad that face each other extend downward.

13. A semiconductor device comprising:
a source frame having a die pad;
a linear gate frame having a bonding pad spaced from the die pad;
a semiconductor chip mounted on the die pad;
a plurality of wires which electrically connect a source terminal of the semiconductor chip to the die pad and electrically connect a gate terminal of the semiconductor chip to the bonding pad; and
resin which seals the die pad, the bonding pad, the semiconductor chip, and the plurality of wires, wherein the gate frame is wider at the bonding pad than elsewhere.

14. The semiconductor device according to claim 13, wherein portions of the die pad and the bonding pad that face each other are respectively cut in a direction diagonal to an extending direction of the gate frame.

15. The semiconductor device according to claim 13, wherein portions of the die pad and the bonding pad that face each other have a stepped shape.

16. A semiconductor device comprising:
a source frame having a die pad;
a gate frame having a bonding pad spaced from the die pad;
a semiconductor chip mounted on the die pad;
a plurality of wires which electrically connect a source terminal of the semiconductor chip to the die pad and electrically connect a gate terminal of the semiconductor chip to the bonding pad; and
resin which seals the die pad, the bonding pad, the semiconductor chip, and the plurality of wires, wherein the die pad surrounds an outer perimeter of the bonding pad in a U shape.

17. A semiconductor device comprising:
a source frame having a die pad;
a gate frame having a bonding pad spaced from the die pad;
a semiconductor chip mounted on the die pad;
a plurality of wires which electrically connect a source terminal of the semiconductor chip to the die pad and electrically connect a gate terminal of the semiconductor chip to the bonding pad; and
resin which seals the die pad, the bonding pad, the semiconductor chip, and the plurality of wires, wherein the bonding pad surrounds an outer perimeter of the die pad in an L shape.

18. A semiconductor device comprising:
a source frame having a die pad;
a gate frame having a bonding pad spaced from the die pad;
a semiconductor chip mounted on the die pad;
a plurality of wires which electrically connect a source terminal of the semiconductor chip to the die pad and electrically connect a gate terminal of the semiconductor chip to the bonding pad; and
resin which seals the die pad, the bonding pad, the semiconductor chip, and the plurality of wires, wherein portions of the die pad and the bonding pad that face each other have an inter-digitated structure.

19. A semiconductor device comprising:
a source frame having a die pad;
a gate frame having a bonding pad spaced from the die pad;
a semiconductor chip mounted on the die pad;
a plurality of wires which electrically connect a source terminal of the semiconductor chip to the die pad and electrically connect a gate terminal of the semiconductor chip to the bonding pad; and
resin which seals the die pad, the bonding pad, the semiconductor chip, and the plurality of wires, wherein the bonding pad is disposed above the die pad.

20. A semiconductor device comprising:
a source frame having a die pad;
a gate frame spaced from the die pad;
a semiconductor chip mounted on the die pad;
a plurality of wires which electrically connect a source terminal of the semiconductor chip to the die pad and electrically connect a gate terminal of the semiconductor chip to the gate frame; and
resin which seals the die pad, the bonding pad, the semiconductor chip, and the plurality of wires, wherein the gate frame is disposed below the die pad.

21. A semiconductor device comprising:
a source frame having a die pad;
a gate frame having a bonding pad spaced from the die pad;
a semiconductor chip mounted on the die pad;
a plurality of wires which electrically connect a source terminal of the semiconductor chip to the die pad and electrically connect a gate terminal of the semiconductor chip to the bonding pad; and
resin which seals the die pad, the bonding pad, the semiconductor chip, and the plurality of wires, wherein the die pad extends below the bonding pad.

22. A semiconductor device comprising:
a source frame having a die pad;
a gate frame having a bonding pad spaced from the die pad;
a semiconductor chip mounted on the die pad;
a plurality of wires which electrically connect a source terminal of the semiconductor chip to the die pad and electrically connect a gate terminal of the semiconductor chip to the bonding pad; and
resin which seals the die pad, the bonding pad, the semiconductor chip, and the plurality of wires, wherein portions of the die pad and the bonding pad that face each other extend downward.
